(19) United States
(12) Patent Application Publication
(10) Pub. No.: US 2016/0035945 A1
(43) Pub. Date: Feb. 4, 2016

(54) WHITE LED CHIP AND METHOD OF MANUFACTURE

(71) Applicant: APT Electronics Ltd., Guangzhou (CN)

(72) Inventors: Chuiming WAN, Guangzhou (CN); Zhirong JIANG, Guangzhou (CN); Yihui WU, Guangzhou (CN); Shuguang YAO, Guangzhou (CN); Zhaoming ZENG, Guangzhou (CN); Guowei XIAO, Guangzhou (CN)

(21) Appl. No.: 14/586,112

(22) Filed: Dec. 30, 2014

(30) Foreign Application Priority Data
Jul. 29, 2014 (CN) 201410367889.7

(51) Int. Cl. H01L 33/50; H01L 33/38; H01L 33/54; H01L 33/32

(52) U.S. Cl. CPC H01L 33/505; H01L 33/32; H01L 33/501; H01L 33/385; H01L 33/54; H01L 2933/0041; H01L 2933/005; H01L 2933/0033

(57) ABSTRACT

The present invention discloses a white LED chip and method of manufacturing the same. The white LED chip includes a flip blue LED chip and a preformed conversion layer for light conversion, the method of manufacturing the white LED chip includes the steps of preparing for a preformed conversion layer for light conversion, setting up at least one cavity on the conversion layer, for receiving a blue LED chip(s), attaching the blue LED chip into the cavity; and cutting the conversion layer into a single white LED chip based on each cavity that received a blue LED chip. The invention not only enhance the luminous efficiency of the white LED chip, but also avoid the pollution to bottom electrode of the LED chip, making easier manufacture and higher binning yield.

### CROSS-REFERENCE TO RELATED APPLICATION

The present application claims priority of Chinese Patent Application No. CN 201410367889.7 filed Jul. 29, 2014, the entire content of which is incorporated herein by reference.

### FIELD OF THE INVENTION

The present invention relates to a light emitting diode (LED), in particular a LED chip package without a substrate and a method of manufacturing the same.

### BACKGROUND INFORMATION

White LED chip fabricated by Chip Scale Package (hereinafter referred to as “CSP”) technology is directly emitting white light. It has several unique advantages, such as smaller volume, larger emitting angle, being driven at large current, low manufacturing cost, easily designed by application etc.

General structure of white LED chip includes flip blue LED chip coated with phosphor conversion layer except its bottom where a conductive pad is located. The phosphor conversion layer, which coated the four sides and top surface of blue LED chip, is generally accomplished by molding and pressing half curing silicone base, using same materials. US patent application No. US 2013/0183777 discloses a LED chip attached on the substrate by reflow soldering, further forming phosphor layer using wafer level mold, which protect for electrode, phosphor conversion layer is prepared by Injection Molding method. However, the molding process is difficult to be realized and aligned. US patent application No. US 2013/0029439 discloses method of manufacturing a white LED chip, wherein the flip type LED chips are arranged on a temporary carrier plate, surrounded by baffles, then dispensing phosphor mixed with silicone and scraping, cutting into a single. This process cause bottom pad to be a bad conduction. Chinese patent application no. CN 201120150362 discloses a white LED chip used by face up type structure, it blocks electrodes using photoresist first, and then spin-coats phosphor layer on it, but the phosphor layer is poor uniformity.

### SUMMARY

The invention provide a white LED chip and method of manufacturing the white LED chips, which solves the problems of polluting LED chip's electrode, leading to bad welding and white LED chip light emitting uniformity.

In order to achieve the purpose of the invention, the present invention provides the following technical scheme.

A white LED chip includes a blue LED chip and a preformed conversion layer. The conversion layer has a cavity which receives the blue LED chip. The four sides and emitting surface of the blue LED chip are wrapped by the cavity.

Further, thickness of the converting layer is 100-1000 um.

Further, the converted layer is made up of one kind or several kinds of materials, including ceramic, silicone, epoxy or glass.

Further, the area of the cavity in the conversion layer is 1.0-1.2 times the area of the blue LED chip, and the height of the cavity is less than or equal to 30% of the height of the conversion layer.

Further, the surface of the cavity is provided with a positioning pattern. The white LED chip can be flip type chip, face up type chip and vertical type chip. The cavity of the flip type LED chip has positioning flutings in cross-shaped, circular or square thereon. The cavity of the face up type LED chip has more than two holes in cross-shaped, circular or square thereon. The cavity of the vertical type LED chip has more than one hole in cross-shaped, circular or square thereon.

Further the white LED chip contains flip blue LED chip, including epitaxial layer, N type gallium nitride layer on the epitaxial layer, active layer on a part of the N type gallium nitride layer, N type ohmic contact layer on a part of the N type gallium nitride layer, P type gallium nitride layer on the active layer and P type ohmic contact on a part of the P type gallium nitride layer. An insulation layer is set on the P type gallium nitride layer, the P type ohmic contact, N type gallium nitride layer and N type ohmic contact. A first through hole is set on the insulation layer on the P type ohmic contact layer, a second through hole is set on the insulation layer on the N type ohmic contact layer. There are P type bonding pad and N type bonding pad on the insulation layers respectively. The P type bonding pad is electric-connected to the P type ohmic contact layer through the first through hole, and the N type bonding pad is electric-connected to the N type ohmic contact layer through the second through hole.

A method of manufacturing the white LED chip includes the following steps:
(1) Preparing for a preformed conversion layer for light conversion;
(2) Setting up at least one cavity on the conversion layer, for receiving a blue LED chip(s).
(3) Attaching the blue LED chip into the cavity.
(4) Cutting the conversion layer into a single white LED chip based on each cavity that received a blue LED chip.

Further the surface of the cavity is provided with the positioning pattern, and the blue LED chip has a positioning portion corresponding to the positioning pattern precisely, such that the blue LED chip can be placed into the cavity.

Further the white LED chip is a flip-type LED chip, the conversion layer of which is prepared by pre-molding, the positioning pattern on the cavity was made by the mold, and the pattern is selected from one or more shapes, including cross, circular and square.

Further the white LED chip also includes a face up type LED chip and a vertical type LED chip, the positioning pattern on the cavities of both chips are stamped by punching mold, the positioning pattern is selected from one or more shapes, including cross, circular and square.

Further the conversion layer is B-stage type polymer material, the blue LED chip is attached to the cavity in the conversion layer, by thermal curing.

Further the conversion layer is a ceramic base fluorescent film, the blue LED chip is attached to the cavity by transparent silicone adhesive paste.

Further the white LED chip contains flip blue LED chip, including epitaxial layer, N type gallium nitride layer on the epitaxial layer, active layer on a part of the N type gallium nitride layer, N type ohmic ohmic contact later on a part of the N type gallium nitride layer, P type gallium nitride layer on the active layer and P type ohmic contact on a part of the P type gallium nitride layer. An insulation layer is set on the P type gallium nitride layer, the P type ohmic contact, N type gallium nitride layer and N type ohmic contact. A first through hole is set on the insulation layer on the P type ohmic contact layer, a second through hole is set on the insulation layer on the N type ohmic contact layer. There is P type bonding pad and N type bonding pad on the insulation layer respectively. The p type bonding pad is electric-connected to the P type ohmic contact through the first through hole, and the N type bonding pad is electric-connected to the N type ohmic contact layer through the second through hole.

Further the white LED chip contains face up type blue LED chip, including epitaxial layer, N type gallium nitride layer on the epitaxial layer, active layer on a part of the N type gallium nitride layer, N type ohmic contact layer on a part of the N type gallium nitride layer, P type gallium nitride layer on the active layer and P type ohmic contact on a part of the P type gallium nitride layer. A transparent conductive pad covers the P type ohmic contact layer. An insulation layer covers a part of surface of the transparent conductive pad. A first pad and a second pad are configured on the surfaces of the N type ohmic contact layer and the insulation layer respectively.

Further the white LED chip contains vertical type blue LED chip, including metal layer, P type gallium nitride layer on the metal payer, active layer on a part of the P type gallium nitride layer, N type gallium nitride layer on the active layer and N type ohmic contact layer on a part of the N type gallium nitride layer. A metal pad is configured on the N type ohmic contact layer.

In the present invention, the blue LED chip is directly attached on the preformed conversion layer, and wrapped by the conversion layer. Such structure is favorable to use a flip blue LED chip attached to the preformed conversion layer, to avoid the pollution to bottom electrode of the white LED chip, and improve welding yield to the white LED chip.

Therefore, the invention not only enhance the luminous efficiency of the white LED chip, but also avoid the pollution to bottom electrode of the LED chip, making easier manufacture and higher binning yield.

### BRIEF DESCRIPTION OF THE DRAWINGS

The present invention will be further described in details hereinafter with the reference to accompanying drawings and exemplary embodiment.

FIG. 1a is schematic diagram of the structure of the flip type white LED chip having conversion layer, according to the present invention;

FIG. 1b is schematic diagram of the structure of the flip type white LED chip without conversion layer, according to the present invention;

FIG. 2 is schematic diagram of the structure of the face up type white LED chip according to the present invention;

FIG. 3 is schematic diagram of the structure of the vertical type white LED chip according to the present invention;

FIGS. 4a-4b are schematic diagrams of first structure of the cavity in Embodiment 1, according to the present invention;

FIGS. 5a-5b are schematic diagram of second structure of the cavity in Embodiment 1, according to the invention;

FIGS. 6a-6b are schematic diagram of third structure of the cavity in Embodiment 1, according to the invention;

FIGS. 7a-7b are schematic diagram of fourth structure of the cavity in Embodiment 1, according to the invention;

FIG. 8 is schematic diagram of the structure of the white LED in Embodiment 1, according to the invention;

FIGS. 9a-9b are schematic diagram of first structure of the cavity in Embodiment 2, according to the invention;

FIGS. 10a-10b are schematic diagram of second structure of the cavity in Embodiment 2, according to the invention;

FIGS. 11a-11b are schematic diagram of third structure of the cavity in Embodiment 2, according to the invention;

FIGS. 12a-12b are schematic diagram of first structure of the cavity in Embodiment 3, according to the invention;

FIGS. 13a-13b are schematic diagram of second structure of the cavity in Embodiment 3, according to the invention; and

FIGS. 14a-14b are schematic diagram of third structure of the cavity in Embodiment 3, according to the invention.

### LIST OF REFERENCE CHARACTERS

100 flip type LED chip
101 epitaxial layer
102 N type gallium nitride layer
103 light emitting layer
104 N type ohmic contact layer
105 P type gallium nitride layer
106 P type ohmic contact layer
107 insulating layer
108 P Type electrode bonding layer
109 N type electrode bonding layer
200 light conversion layer sheet
300 electrode bonding layer
400 electrode bonding layer

### DETAILED DESCRIPTION

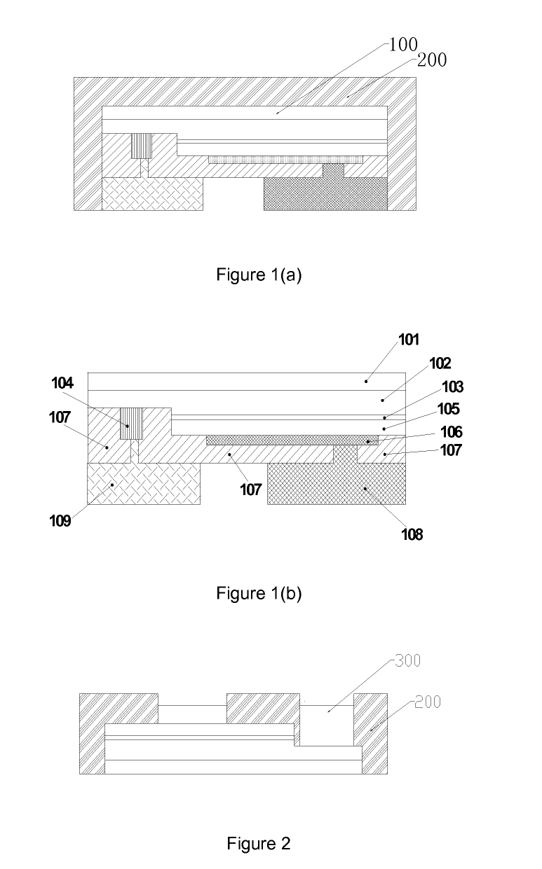

As shown in FIGS. 1a, 2 and 3, the embodiment discloses a white LED chip including a blue LED chip 100 and a preformed conversion layer 200 for light conversion.

The blue LED chip 100 is flip chip. A cavity is set in the conversion layer, the blue LED chip is configured within the cavity, the four sides and emitting surface of the blue LED chip are wrapped by the cavity. Therefore white light is fabricated by mixing blue light from LED chip 100 and the light through conversion layer 200.

Preferably, the conversion layer is a thin film, the thickness of which is 100-1000 um, and its base material is one or various combination, selected from ceramic, silicone, epoxy and glass.

The method of preparing for conversion film can be, for example,

1) Phosphor is mixed with ceramic power, the mixture can be made to a flat conversion layer by pressing, sintering, polishing and cutting process, and then the conversion layer is coated by photosensitive epoxy polymer, to form a conversion sheet which make up of several cavities by means of exposure, development and shaping process; or

2) Phosphor is mixing glass powder, the mixture can be made to a flat glass conversion layer by high temperature sintering, grinding, polishing and cutting process, then the glass conversion layer is coated by silicone materials mixed with phosphor, to form a conversion sheet which make up of several cavities.

Preferably the conversion layer make from B-stage type polymer materials, the blue LED chip is attached to the cavity on the conversion layer, by thermal curing.

Alternatively the conversion layer can be ceramic base converting layer, the blue LED chip is attached to the cavity by transparent silicone adhesive paste.

The volume of the cavity is the length times the width times the height, the area of the cavity is the length times the width. The area of the cavity is 1.0-1.2 times of the area of the blue LED chip, and the height of cavity is no more than 30% of the height of the conversion layer.

The conversion layer 200 is a preformed thin film being strip-shaped or piece-shaped. The conversion 200 is used for light conversion, for example, when the blue LED chip 100 emitted blue light, the yellow color conversion layer 200 can be selected, such that blue light from the LED chip 100 will be converted to white light. Anyway the invention not only applies to this instance, i.e. the use of blue LED chip and yellow conversion layer, but also other conversion from other color light to white light. The conversion layer 200 is made of carrier materials and conversion materials dispersed among the carrier materials. The conversion materials include matrix and activator. The matrix is made of one or various combination materials, selected from nitride, silicate, YAG, LuAG, fluoride and phosphate. The activator is made of one or various combination materials, selected from Eu2+, Pr3+, Ce3+, Eu3+, Tb3+, Yb2+, Dy3+. The carrier material is transparent inorganic materials that are Al2O3 and SiO2. The preformed conversion layer is made by the steps: a. mixing A12O3 with phosphor; b. the mixture can be made to a film conversion layer by pressing, sintering, polishing and cutting process.

### Embodiment 1

As shown in FIG. 1b, the white LED chip contains flip blue LED chip 100, including epitaxial layer 101, N type gallium nitride layer 102 on the epitaxial layer 101, active layer 103 on a part of the N type gallium nitride layer 102, N type ohmic contact layer 104 on a part of the N type gallium nitride layer 102, P type gallium nitride layer 105 on the active layer 103 and P type ohmic contact 106 on a part of the P type gallium nitride layer 105. An insulation layer 107 is set on the P type gallium nitride layer 105, the P type ohmic contact layer 106, N type gallium nitride layer 102 and N type ohmic contact layer 104. The first through hole is set on the insulation layer 107 on the P type ohmic contact layer 106, the second through hole is set on the insulation layer 107 on the N type contact ohmin layer 104. There are P type bonding pad 108 and N type bonding pad 109 on the insulation layer 107 respectively. The P type bonding pad 108 is electric-connected to the P type ohmic contact layer 106 through the first through hole, and the N type bonding pad 109 is electric-connected to the N type ohmic contact layer 104 through the second through hole.

The method of manufacturing the white LED chip includes the following steps::

(1) Preparing for a preformed conversion layer for light conversion.

The conversion layer 200 must be preformed in advance.

(2) Setting up at least one cavity on the conversion layer, for receiving blue LED chip(s).

Several cavities are configured on the conversion layer 200, for receiving blue LED chips, and the surface of the cavity is provided with the positioning pattern being selected from one or more shapes, including cross, circular and square. As shown in FIG. 1a, the blue LED chip 100 is flip chip. P type bonding pad 108 and N type bonding pad 109 face down, and are not covered by the conversion layer 200. Thus the positioning pattern must be flutings, and cannot be the through hole, in order to prevent the light from emitting improperly.

(3) Attaching the blue LED chip into the cavity.

As shown in FIG. 1a, the blue LED chip is attached into the cavity.

(4) Cutting the conversion layer into a single white LED chip based on each cavity that received a blue LED chip.

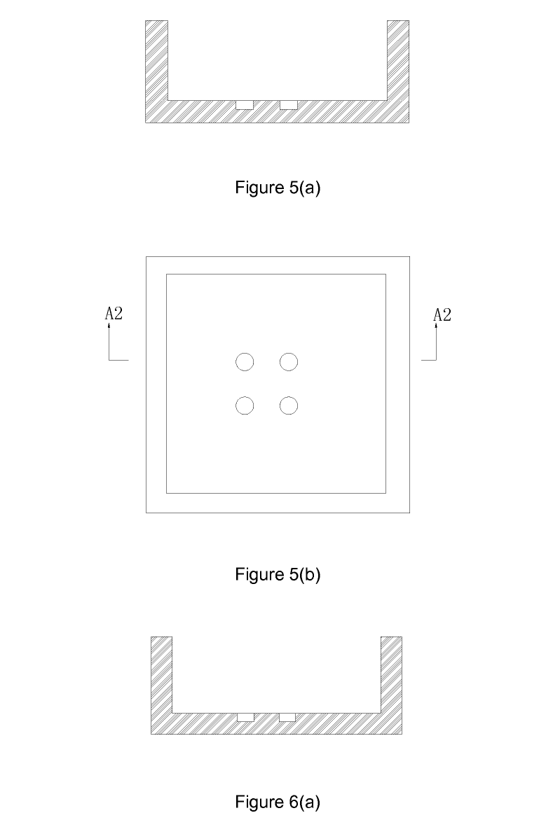

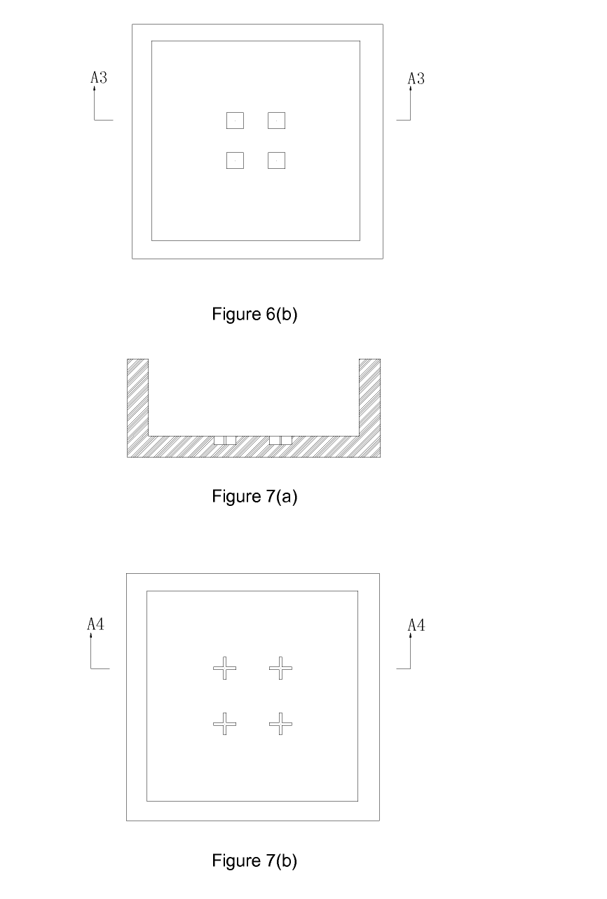

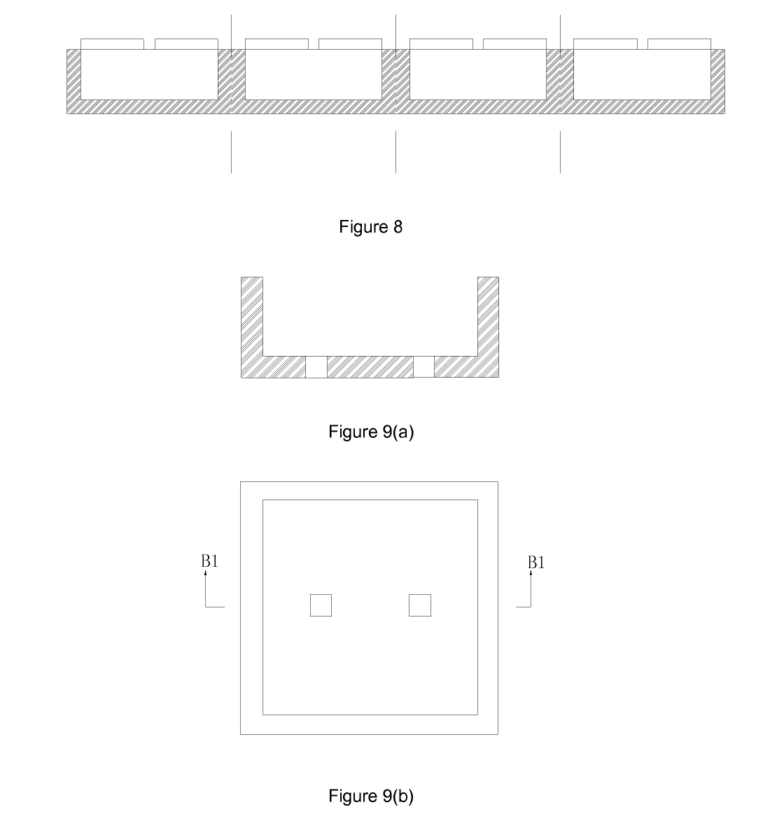

Several cavities are configured on the conversion layer, and one blue LED chip can be attached to one cavity. When the conversion layer is cut and split into a plurality of single white LED chips, each white LED chip will be covered by the conversion layer except the P type bonding pad 108 and N type bonding pad 109. FIG. 4(b), FIG. 5(b), FIG. 6(b) and FIG. 7(b) are the bottom views of the conversion layer in which the cavities are configured. Accordingly, FIG. 4(a) is the cross-section view along A1-A1 of FIG. 4(b); FIG. 5(a) is the cross-section view along A2-A2 of FIG. 5(b); FIG. 6(a) is the cross-section view along A3-A3 of FIG. 6(b); FIG. 7(a) is the cross-section view along A4-A4 of FIG. 7(b). As shown in the FIG. 4-7, there are several positioning flutings, such as cross-shaped, circular and square, in the cavity. The blue LED chip can be attached to the cavity using flip type bonding, die bonding and SMT machine. The blue LED chip 100 can be attached to the conversion layer 200 using transparent adhesive. As shown in FIG. 8, the conversion layer can be cut by the cutter, along the dotted line, and split into a plurality of single white LED chips.

The method is different from the conventional phosphor coating method, a preformed conversion layer 200 is made, and several cavities are configured on the conversion layer. The blue LED chips are attached to the cavities. The sides and emitting surface of the blue LED chip are wrapped by the conversion layer, that avoid the pollution to bottom electrode of the white LED chip, and improve welding yield to the white LED chip.

### Embodiment 2

As shown in FIGS. 2 and 9-11, the white LED chip contains face up type blue LED chip, including epitaxial layer, N type gallium nitride layer on the epitaxial layer, active layer on a part of the N type gallium nitride layer, and N type ohmic contact layer on a part of the N type gallium nitride layer, P type gallium nitride layer on the active layer and P type ohmic contact layer on a part of the P type gallium nitride layer. A transparent conductive pad covers the P type ohmic contact layer. An insulation layer covers a part of surface of the transparent conductive pad. A first pad and a second pad are configured on the surfaces of the N type ohmic contact layer and the insulation layer respectively.

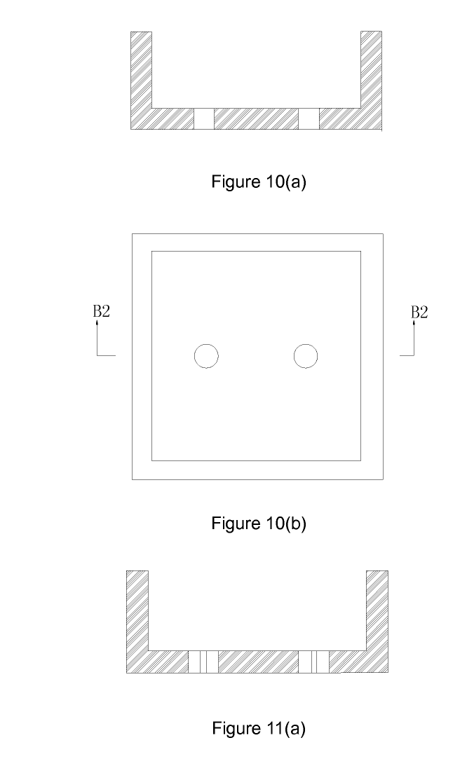

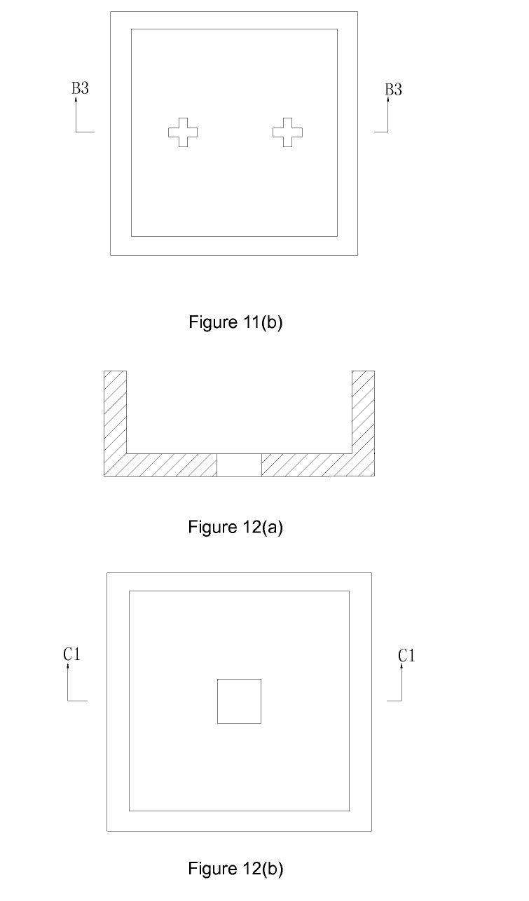

Several cavities are configured by die stamping, on the conversion layer, each cavity can receive one blue LED chip and has a through hole. The position of the hole is corresponding to the electrode wire of the blue LED chip. As shown in FIGS. 9-11, FIG. 9(b), 10(b), 11(b) are the bottom views of each cavity on the conversion layer. Accordingly, FIG. 9(a) is the cross-section view along B1-B1 of FIG. 9(b); FIG. 10(a) is the cross-section view along B2-B2 of FIG. 10(b); FIG. 11(a) is the cross-section view along B3-B3 of FIG. 11(b). The shape of hole can be cross, circular or square.

Each face up type LED chip 100 is attached to the cavity on the conversion layer 200, the sides and emitting surface of the LED ship are wrapped by the conversion layer, whereby a single white LED chip is formed.

### Embodiment 3

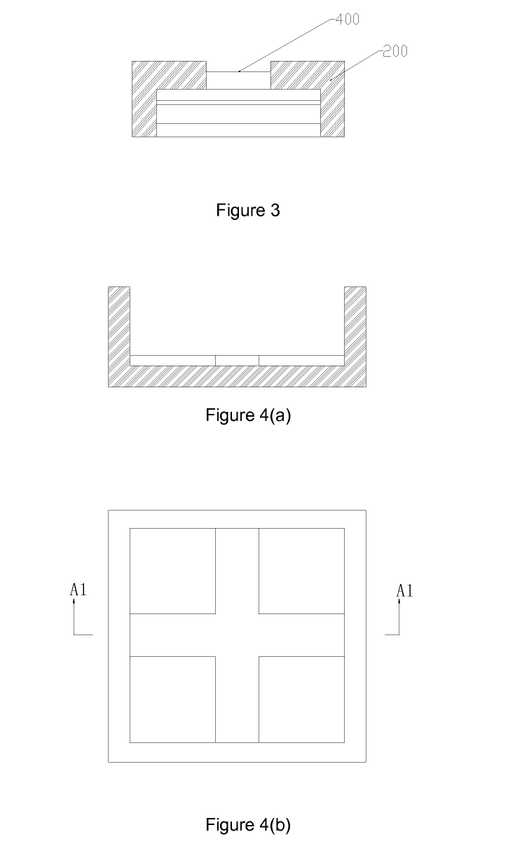

As shown in FIGS. 3, 12-14, the white LED chip contains vertical type blue LED chip, including metal layer, P type gallium nitride layer on the metal payer, active layer on a part of the P type gallium nitride layer, N type gallium nitride layer on the active layer and N type ohmic contact on a part of the N type gallium nitride layer. A metal pad is configured on the N type ohmic contact layer.

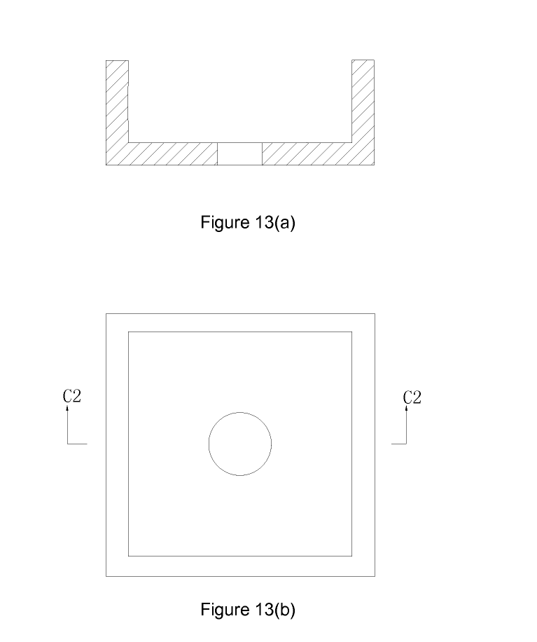

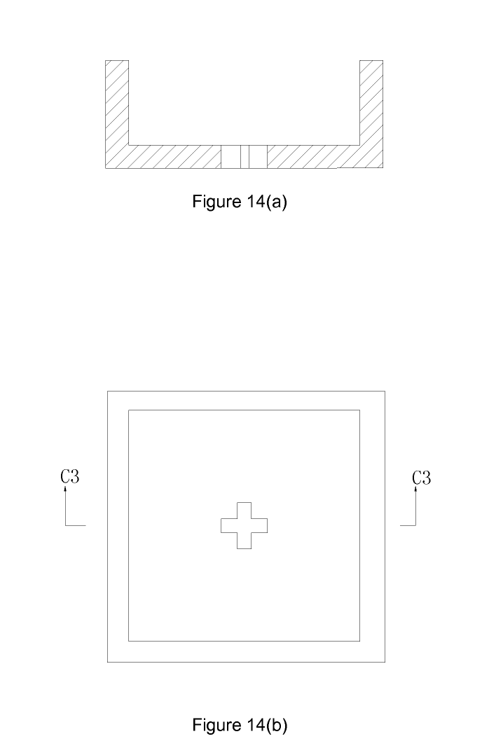

Several cavities are configured by die stamping, on the conversion layer, each cavity can receive one blue LED chip and has a through hole. The position of the hole is corresponding to the electrode wire of the blue LED chip. As show in FIGS. 12-14, FIG. 12(b), 13(b), 14(b) are the bottom views of each cavity on the conversion layer. Accordingly, FIG. 12(a) is the cross-section view along C1-C1 of FIG. 12(b); FIG. 13(a) is the cross-section view along C2-C2 of FIG. 13(b); FIG. 14(a) is the cross-section view along C3-C3 of FIG. 14(b).The shape of hole can be cross, circular, square.

Each vertical type blue LED chip 100 is attached to the cavity on the conversion layer 200, the sides and emitting surface of the blue LED chip are wrapped by the conversion layer, whereby a single white LED chip is formed.

The foregoing descriptions are exemplary embodiments only. It will be apparent to those skilled in the art that various modifications and variations can be made in the present inventions without departing from the spirit or scope of the invention. Therefore, all such logic analysis, ratiocinations and solutions based on limit experiments are intended to be embraced within the scope of the invention as defined in the appended claims.

What is claimed is:

1. A white LED chip, comprising a blue LED chip and a preformed conversion layer, the conversion layer has a cavity which receives the blue LED chip, the four sides and emitting surface of the blue LED chip are wrapped by the cavity.

2. The white LED chip of claim 1, wherein a thickness of the conversion layer is 100 um-1000 um.

3. The white LED chip of claim 1, wherein the conversion layer is made up of one kind or several kinds of materials, including ceramic, silicone, epoxy resin or glass.

4. The white LED chip of claim 1, wherein an area of the cavity is its length times its width, the area of the cavity is 1.0-1.2 times of an area of the blue LED chip, and a height of cavity is no more than 30% of a height of the conversion layer.

5. The white LED chip of claim 1, wherein the surface of the cavity is provided with a positioning pattern; the white LED chip includes flip type LED chip , face up type LED chip and vertical type LED chip; the cavity of the flip type LED chip has a positioning flutings in cross-shaped, circular or square thereon; the cavity of the face up type LED chip has more than two holes in cross-shaped, circular or square thereon; the cavity of the vertical type LED chip has more than one hole in cross-shaped, circular or square thereon.

6. The white LED chip of claim 5, wherein the white LED chip contains flip blue LED chip, including epitaxial layer, N type gallium nitride layer on the epitaxial layer, active layer on a part of the N type gallium nitride layer, N type ohmic contact layer on a part of the N type gallium nitride layer, P type gallium nitride layer on the active layer and P type ohmic contact layer on a part of the P type gallium nitride layer; an Insulation layer is set on the P type gallium nitride layer, the P type ohmic contact, N type gallium nitride layer and N type ohmic contact; a first through hole is set on the insulation layer on the P type ohmic contact layer, a second through hole is set on the insulation layer on the N type ohmic contact layer; there are P type bongding pad and N type bonding pad on the insulation layers respectively; the P type bonding pad is electric-connected to the P type ohmic contact layer through the first through hole, and the N type bonding pad is electric-connected to the N type ohmic contact layer through the second through hole.

7. A method of manufacturing a white LED chip, including the steps of
(1) Preparing for a preformed conversion layer for light conversion;
(2) Setting up at least one cavity on the conversion layer, for receiving a blue LED chip(s);
(3) Attaching the blue LED chip into the cavity; and
(4) Cutting the conversion layer into a single white LED chip based on each cavity that received a blue LED chip.

8. The method of claim 7, wherein the surface of the cavity is provided with a positioning pattern, and the blue LED chip has a positioning portion corresponding to the positioning pattern precisely, such that the blue LED chip can be placed in to the cavity.

9. The method of claim 8, wherein the white LED chip is a flip type LED chip, the conversion layer of which is prepared by pre-molding, the positioning pattern on the cavity was made by the mold, and the pattern is selected from one or more shapes, including cross, circular, square.

10. The method of claim 8, wherein the white LED chip includes a face up type LED chip and a vertical type LED chip, the positioning pattern on the cavity of both chips are stamped by punching mold, the positioning pattern is selected from one or more shapes, including cross, circular and square.

11. The method of claim 7, wherein the conversion layer is a B-stage polymer material, and the blue LED chip is attached to the cavity in the conversion layer, by thermal curing; and
the conversion layer is a ceramic based fluorescent film, the blue LED chip is attached to the cavity by transparent adhesive.
